(19) United States
(12) Patent Application Publication
(10) Pub. No.: US 2026/0212898 A1
(43) Pub. Date: Jul. 23, 2026

(54) MEMORY UNIT HAVING HIGH MANUFACTURING CAPABILITY

(71) Applicant: TAIWAN SEMICONDUCTOR MANUFACTURING COMPANY, LTD., Hsinchu (TW)

(72) Inventor: Jhon Jhy LIAW, Hsinchu (TW)

(73) Assignee: TAIWAN SEMICONDUCTOR MANUFACTURING COMPANY, LTD., Hsinchu (TW)

(21) Appl. No.: 19/027,702

(22) Filed: Jan. 17, 2025

(51) Int. Cl. G11C 5/06

(52) U.S. Cl. CPC G11C 5/063

(57) ABSTRACT

A memory unit includes a first memory cell, a second memory cell, a VDD line segment, a non-inverting bit line segment and an inverting bit line segment. The first memory cell and the second memory cell are located in a transistor layer, and are adjacent to each other in a first direction. The VDD line segment is located in a first metal layer stacked on the transistor layer, extends along a second direction, and is electrically connected to the first memory cell. The non-inverting bit line segment and the inverting bit line segment are located in a second metal layer stacked on the first metal layer, each extend along the second direction, and each are electrically connected to the first memory cell and the second memory cell.

### BACKGROUND

The semiconductor integrated circuit (IC) industry has, over the decades, experienced tremendous advancements and is still undergoing vigorous development. With dramatic advances in technology, the industry pays much attention to the development of memory units with high manufacturing capability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating a memory device in accordance with some embodiments.

FIG. 2 is a circuit diagram illustrating a memory cell in accordance with some embodiments.

FIG. 3 is a circuit diagram illustrating a memory cell in accordance with some embodiments.

FIG. 4 is a schematic diagram illustrating relative positions (in a Z direction) of various layers of a memory device in accordance with some embodiments.

FIGS. 5 and 6 are schematic diagrams illustrating relative positions (in an X direction and a Y direction) of various components of a memory device in accordance with some embodiments.

FIG. 7 is a schematic diagram illustrating relative positions (in an X direction and a Y direction) of various components of a memory device in accordance with some embodiments.

FIGS. 8 and 9 are schematic diagrams illustrating relative positions (in an X direction and a Y direction) of various components of a memory device in accordance with some embodiments.

FIG. 10 is a schematic diagram illustrating relative positions (in an X direction and a Y direction) of various components of a memory device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

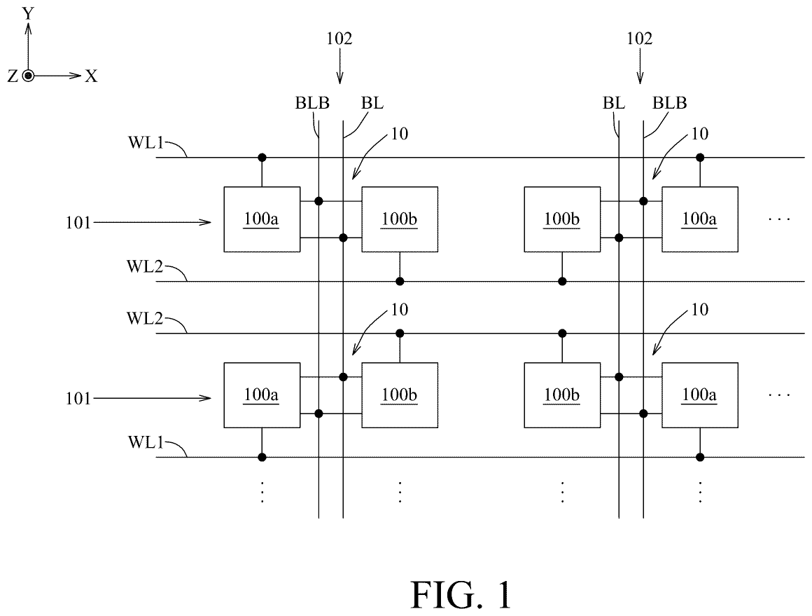

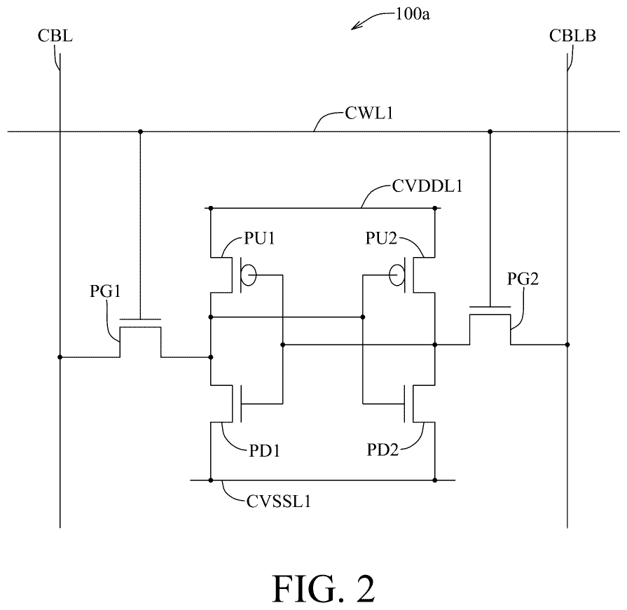

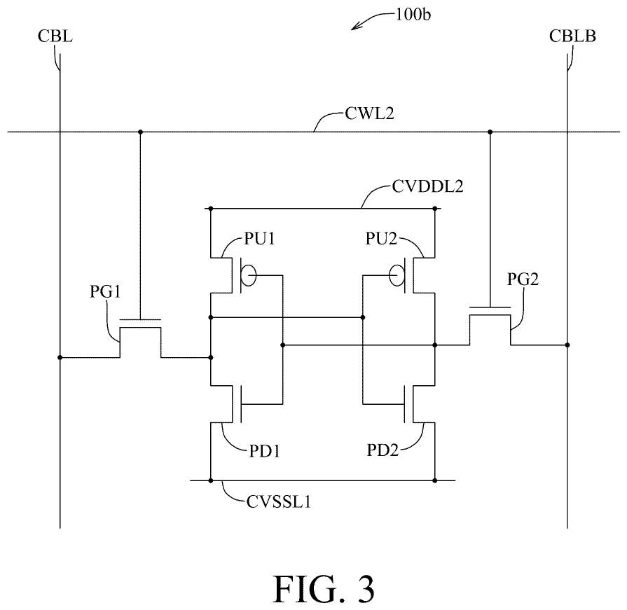

FIG. 1 is a block diagram illustrating a memory device in accordance with some embodiments. FIG. 2 is a circuit diagram illustrating a memory cell in accordance with some embodiments. FIG. 3 is a circuit diagram illustrating a memory cell in accordance with some embodiments. Referring to FIGS. 1 to 3, the memory device includes a plurality of memory units 10. The memory cells 100 are arranged in a matrix that has a plurality of columns 102 aligned in a first direction (e.g., an X direction transverse to a Z direction, where the Z direction points from bottom to top of the memory device) and a plurality of rows 101 aligned in a second direction (e.g., a Y direction transverse to the X direction and the Z direction).

Each of the memory units 10 includes a first memory cell (100a), a second memory cell (100b), a non-inverting bit line segment (CBL), an inverting bit line segment (CBLB), a first word line segment (CWL1), a second word line segment (CWL2), a first VDD line segment (CVDDL1), a second VDD line segment (CVDDL2), a first VSS line segment (CVSSL1), a second VSS line segment (not shown), a third VSS line segment (not shown) and a fourth VSS line segment (not shown).

The memory cells (100a, 100b) of each of the memory units 10 corresponds to each other, and are adjacent to each other in the X direction. Each of the memory cells (100a, 100b) of the memory units 10 is a static random access memory (SRAM) cell, and includes a first pull-up transistor (PU1), a second pull-up transistor (PU2), a first pull-down transistor (PD1), a second pull-down transistor (PD2), a first pass-gate transistor (PG1) and a second pass-gate transistor (PG2). With respect to each of the memory cells (100a, 100b) of the memory units 10, each of the transistors (PU1, PU2, PD1, PD2, PG1, PG2) includes a gate electrode, a first source/drain region and a second source/drain region. The first source/drain region of the first pull-up transistor (PU1), the first source/drain region of the first pull-down transistor (PD1), the first source/drain region of the first pass-gate transistor (PG1), the gate electrode of the second pull-up transistor (PU2) and the gate electrode of the second pull-down transistor (PD2) are electrically connected to each other. The first source/drain region of the second pull-up transistor (PU2), the first source/drain region of the second pull-down transistor (PD2), the first source/drain region of the second pass-gate transistor (PG2), the gate electrode of the first pull-up transistor (PU1) and the gate electrode of the first pull-down transistor (PD1) are electrically connected to each other. With respect to each of the memory units 10, the second source/drain region of the first pull-up transistor (PU1) of the first memory cell (100a) and the second source/drain region of the second pull-up transistor (PU2) of the first memory cell (100a) are electrically connected to the first VDD line segment (CVDDL1). The second source/drain region of the first pull-up transistor (PU1) of the second memory cell (100b) and the second source/drain region of the second pull-up transistor (PU2) of the second memory cell (100b) are electrically connected to the second VDD line segment (CVDDL2). The second source/drain region of the first pull-down transistor (PD1) of the first memory cell (100a), the second source/drain region of the second pull-down transistor (PD2) of the first memory cell (100a), the second source/drain region of the first pull-down transistor (PD1) of the second memory cell (100b), and the second source/drain region of the second pull-down transistor (PD2) of the second memory cell (100b) are electrically connected to the first VSS line segment (CVSSL1). The gate electrode of the first pass-gate transistor (PG1) of the first memory cell (100a) and the gate electrode of the second pass-gate transistor (PG2) of the first memory cell (100a) are electrically connected to the first word line segment (CWL1). The gate electrode of the first pass-gate transistor (PG1) of the second memory cell (100b) and the gate electrode of the second pass-gate transistor (PG2) of the second memory cell (100b) are electrically connected to the second word line segment (CWL2). The second source/drain region of the first pass-gate transistor (PG1) of the first memory cell (100a) and the second source/drain region of the first pass-gate transistor (PG1) of the second memory cell (100b) are electrically connected to the non-inverting bit line segment (CBL). The second source/drain region of the second pass-gate transistor (PG2) of the first memory cell (100a) and the second source/drain region of the second pass-gate transistor (PG2) of the second memory cell (100b) are electrically connected to the inverting bit line segment (CBLB). The second VSS line segment is electrically connected to the first VSS line segment (CVSSL1). The third VSS line segment and the fourth VSS line segment are electrically connected to the second VSS line segment. Therefore, with respect to each of the memory cells (100a, 100b) of the memory units 10, the first pull-up transistor (PU1) and the first pull-down transistor (PD1) cooperatively form a first inverter. The second pull-up transistor (PU2) and the second pull-down transistor (PD2) cooperatively form a second inverter. The first inverter and the second inverter are cross-coupled so as to form a data latch for storing data. When the first pass-gate transistor (PG1) and the second pass-gate transistor (PG2) conduct, a write operation and a read operation are allowed to be performed on the data latch.

With respect to each of the columns 102, the first memory cells (100a) of the memory units 10 in the column 102 are aligned in the Y direction, the second memory cells (100b) of the memory units 10 in the column 102 are aligned in the Y direction, the non-inverting bit line segments (CBL) of the memory units 10 in the column 102 are connected in series so as to form a non-inverting bit line (BL) that corresponds to the column 102 and that extends along the Y direction, and the inverting bit line segments (CBLB) of the memory units 10 in the column 102 are connected in series so as to form an inverting bit line (BLB) that corresponds to the column 102 and that extends along the Y direction. With respect to each of the rows 101, the first memory cells (100a) or the second memory cells (100b) of any two adjacent ones of the memory units 10 in the row 101 are adjacent to each other, the first word line segments (CWL1) of the memory units 10 in the row 101 are connected in series so as to form a first word line (WL1) that corresponds to the row 101 and that extends along the X direction, and the second word line segments (CWL2) of the memory units 10 in the row 101 are connected in series so as to form a second word line (WL2) that corresponds to the row 101 and that extends along the X direction.

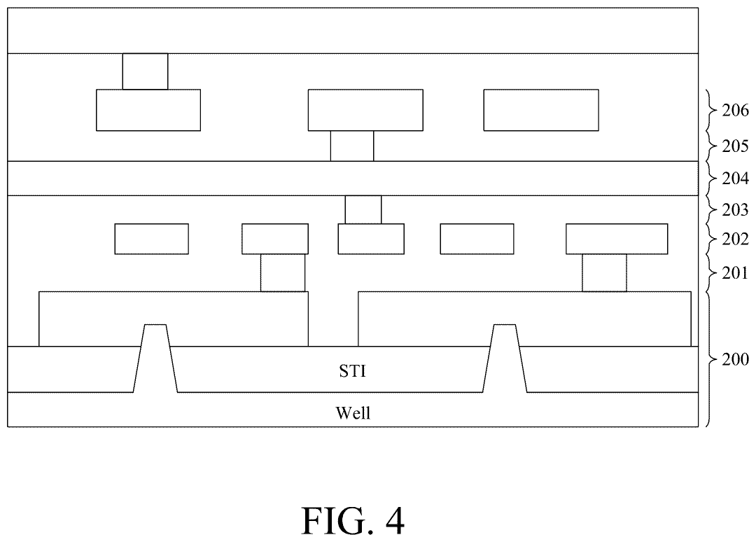

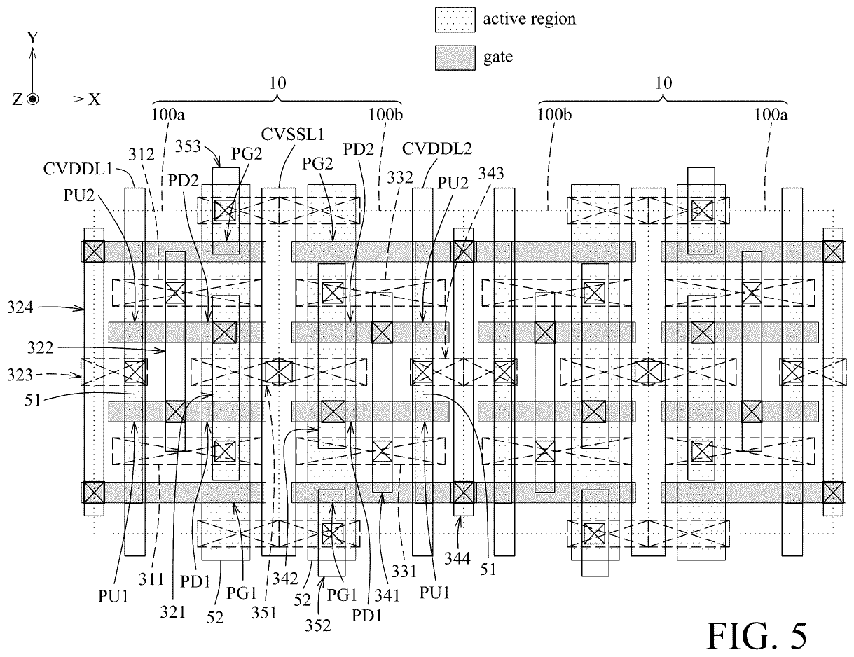

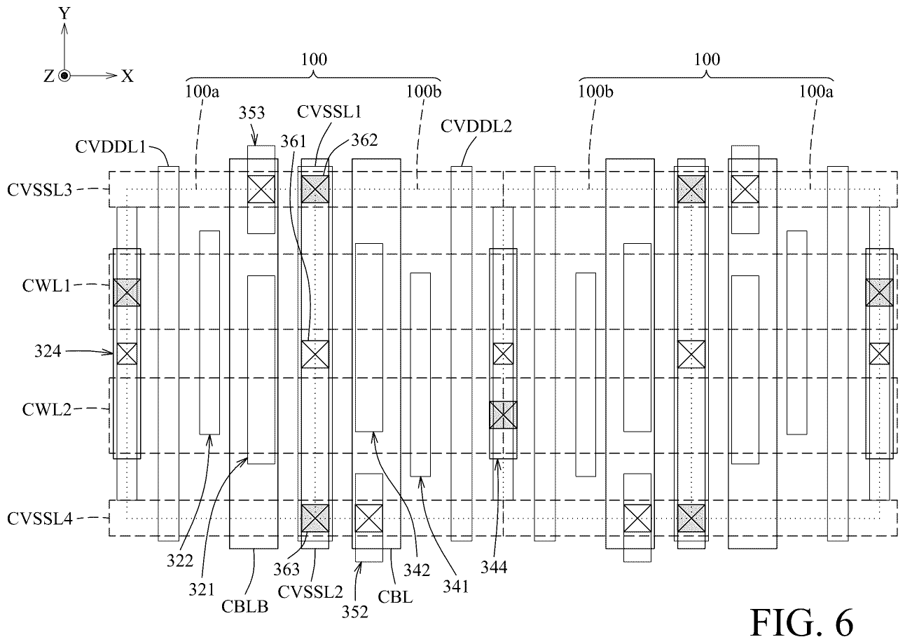

FIG. 4 is a schematic diagram illustrating relative positions (in the Z direction) of various layers of a memory device in accordance with some embodiments. FIGS. 5 and 6 are schematic diagrams illustrating relative positions (in the X direction and the Y direction) of various components of a memory device in accordance with some embodiments. It should be noted that each of FIGS. 5 and 6 omits the depiction of some components of the memory device for the sake of clarity.

Referring to FIGS. 4 to 6, with respect to each of the memory cells (100a, 100b) of the memory units 10, the transistors (PU1, PU2, PD1, PD2, PG1, PG2) are located in a transistor layer 200. The gate electrode of each of the transistors (PU1, PU2, PD1, PD2, PG1, PG2) extends along the X direction. The first source/drain regions and the second source/drain regions of the first pull-up transistor (PU1) and the second pull-up transistor (PU2) are formed in a first active region 51. The first source/drain regions and the second source/drain regions of the first pull-down transistor (PD1), the second pull-down transistor (PD2), the first pass-gate transistor (PG1) and the second pass-gate transistor (PG2) are formed in a second active region 52. The first active region 51 and the second active region 52 are aligned in the X direction, and each extend along the Y direction. The second active region 52 is close to a border of the memory cell (100a/100b) and the corresponding memory cell (100b/100a). With respect to each of the memory units 10, the first VDD line segment (CVDDL1), the second VDD line segment (CVDDL2) and the first VSS line segment (CVSSL1) are located in a first metal layer 202 stacked on the transistor layer 200, and each extend along the Y direction. The first VSS line segment (CVSSL1) is disposed between the first VDD line segment (CVDDL1) and the second VDD line segment (CVDDL2) and on a border of the memory cells (100a, 100b). The non-inverting bit line segment (CBL), the inverting bit line segment (CBLB) and the second VSS line segment (CVSSL2) are located in a second metal layer 204 stacked on the first metal layer 202, and each extend along the Y direction. The second VSS line segment (CVSSL2) is disposed between the non-inverting bit line segment (CBL) and the inverting bit line segment (CBLB) and on the border of the memory cells (100a, 100b). The first word line segment (CWL1), the second word line segment (CWL2), the third VSS line segment (CVSSL3) and the fourth VSS line segment (CVSSL4) are located in a third metal layer 206 stacked on the second metal layer 204, and each extend along the X direction. The first word line segment (CWL1) and the second word line segment (CWL2) are disposed between the third VSS line segment (CVSSL3) and the fourth VSS line segment (CVSSL4), with the first word line segment (CWL1) adjacent to the third VSS line segment (CVSSL3) and the second word line segment (CWL2) adjacent to the fourth VSS line segment (CVSSL4).

With respect to the first memory cell (100a) of each of the memory units 10, the first source/drain region of the first pass-gate transistor (PG1) and the first source/drain region of the first pull-down transistor (PD1) share the same region (i.e., the first pass-gate transistor (PG1) and the first pull-down transistor (PD1) have a common first source/drain region). The common first source/drain region of the first pass-gate transistor (PG1) and the first pull-down transistor (PD1) is connected to the first source/drain region of the first pull-up transistor (PU1) through a contact 311 that is located in an upper portion of the transistor layer 200. The contact 311 is connected to the gate electrode of the second pull-down transistor (PD2) through an interconnect element 321 that includes two vias located in a bottom via layer 201 disposed between the first metal layer 202 and the transistor layer 200, and a landing pad located in the first metal layer 202. The gate electrode of the second pull-down transistor (PD2) and the gate electrode of the second pull-up transistor (PU2) are connected in series. Accordingly, the electrical connection among the first source/drain region of the first pass-gate transistor (PG1), the first source/drain region of the first pull-down transistor (PD1), the first source/drain region of the first pull-up transistor (PU1), the gate electrode of the second pull-down transistor (PD2) and the gate electrode of the second pull-up transistor (PU2) is established. The first source/drain region of the second pass-gate transistor (PG2) and the first source/drain region of the second pull-down transistor (PD2) share the same region (i.e., the second pass-gate transistor (PG2) and the second pull-down transistor (PD2) have a common first source/drain region). The common first source/drain region of the second pass-gate transistor (PG2) and the second pull-down transistor (PD2) is connected to the first source/drain region of the second pull-up transistor (PU2) through a contact 312 that is located in the upper portion of the transistor layer 200. The contact 312 is connected to the gate electrode of the first pull-up transistor (PU1) and the gate electrode of the first pull-down transistor (PD1) through an interconnect element 322 that includes two vias located in the bottom via layer 201, and a landing pad located in the first metal layer 202. Accordingly, the electrical connection among the first source/drain region of the second pass-gate transistor (PG2), the first source/drain region of the second pull-down transistor (PD2), the first source/drain region of the second pull-up transistor (PU2), the gate electrode of the first pull-up transistor (PU1) and the gate electrode of the first pull-down transistor (PD1) is established. The second source/drain region of the first pull-up transistor (PU1) and the second source/drain region of the second pull-up transistor (PU2) share the same region (i.e., the first pull-up transistor (PU1) and the second pull-up transistor (PU2) have a common second source/drain region). The common second source/drain region of the first pull-up transistor (PU1) and the second pull-up transistor (PU2) is electrically connected to the first VDD line segment (CVDDL1) through an interconnect element 323 that includes a contact located in the upper portion of the transistor layer 200, and a via located in the bottom via layer 201. The gate electrode of the first pass-gate transistor (PG1) and the gate electrode of the second pass-gate transistor (PG2) are electrically connected to the first word line segment (CWL1) through an interconnect element 324 that includes two first vias located in the bottom via layer 201, a first landing pad located in the first metal layer 202, a second via located in a first via layer 203 disposed between the second metal layer 204 and the first metal layer 202, a second landing pad located in the second metal layer 204, and a third via located in a second via layer 205 disposed between the third metal layer 206 and the second metal layer 204.

With respect to the second memory cell (100b) of each of the memory units 10, the first source/drain region of the first pass-gate transistor (PG1) and the first source/drain region of the first pull-down transistor (PD1) share the same region (i.e., the first pass-gate transistor (PG1) and the first pull-down transistor (PD1) have a common first source/drain region). The common first source/drain region of the first pass-gate transistor (PG1) and the first pull-down transistor (PD1) is connected to the first source/drain region of the first pull-up transistor (PU1) through a contact 331 that is located in the upper portion of the transistor layer 200. The contact 331 is connected to the gate electrode of the second pull-up transistor (PU2) and the gate electrode of the second pull-down transistor (PD2) through an interconnect element 341 that includes two vias located in the bottom via layer 201, and a landing pad located in the first metal layer 202. Accordingly, the electrical connection among the first source/drain region of the first pass-gate transistor (PG1), the first source/drain region of the first pull-down transistor (PD1), the first source/drain region of the first pull-up transistor (PU1), the gate electrode of the second pull-up transistor (PU2) and the gate electrode of the second pull-down transistor (PD2) is established. The first source/drain region of the second pass-gate transistor (PG2) and the first source/drain region of the second pull-down transistor (PD2) share the same region (i.e., the second pass-gate transistor (PG2) and the second pull-down transistor (PD2) have a common first source/drain region). The common first source/drain region of the second pass-gate transistor (PG2) and the second pull-down transistor (PD2) is connected to the first source/drain region of the second pull-up transistor (PU2) through a contact 332 that is located in the upper portion of the transistor layer 200. The contact 332 is connected to the gate electrode of the first pull-down transistor (PD1) through an interconnect element 342 that includes two vias located in the bottom via layer 201, and a landing pad located in the first metal layer 202. The gate electrode of the second pull-down transistor (PD2) and the gate electrode of the second pull-up transistor (PU2) are connected in series. Accordingly, the electrical connection among the first source/drain region of the second pass-gate transistor (PG2), the first source/drain region of the second pull-down transistor (PD2), the first source/drain region of the second pull-up transistor (PU2), the gate electrode of the first pull-down transistor (PD1) and the gate electrode of the first pull-up transistor (PU1) is established. The second source/drain region of the first pull-up transistor (PU1) and the second source/drain region of the second pull-up transistor (PU2) share the same region (i.e., the first pull-up transistor (PU1) and the second pull-up transistor (PU2) have a common second source/drain region). The common second source/drain region of the first pull-up transistor (PU1) and the second pull-up transistor (PU2) is electrically connected to the second VDD line segment (CVDDL2) through an interconnect element 343 that includes a contact located in the upper portion of the transistor layer 200, and a via located in the bottom via layer 201. The gate electrode of the first pass-gate transistor (PG1) and the gate electrode of the second pass-gate transistor (PG2) are electrically connected to the second word line segment (CWL2) through an interconnect element 344 that includes two first vias located in the bottom via layer 201, a first landing pad located in the first metal layer 202, a second via located in the first via layer 203, a second landing pad located in the second metal layer 204, and a third via located in the second via layer 205.

With respect to each of the memory units 10, the second source/drain region of the first pull-down transistor (PD1) of the first memory cell (100a) and the second source/drain region of the second pull-down transistor (PD2) of the first memory cell (100a) share the same region (i.e., the first pull-down transistor (PD1) of the first memory cell (100a) and the second pull-down transistor (PD2) of the first memory cell (100a) have a common second source/drain region). The second source/drain region of the first pull-down transistor (PD1) of the second memory cell (100b) and the second source/drain region of the second pull-down transistor (PD2) of the second memory cell (100b) share the same region (i.e., the first pull-down transistor (PD1) of the second memory cell (100b) and the second pull-down transistor (PD2) of the second memory cell (100b) have a common second source/drain region). The common second source/drain region of the first pull-down transistor (PD1) of the first memory cell (100a) and the second pull-down transistor (PD2) of the first memory cell (100a) and the common second source/drain region of the first pull-down transistor (PD1) of the second memory cell (100b) and the second pull-down transistor (PD2) of the second memory cell (100b) are electrically connected to the first VSS line segment (CVSSL1) through an interconnect element 351 that includes a contact located in the upper portion of the transistor layer 200, and a via located in the bottom via layer 201. The second source/drain region of the first pass-gate transistor (PG1) of the first memory cell (100a) and the second source/drain region of the first pass-gate transistor (PG1) of the second memory cell (100b) are electrically connected to the non-inverting bit line segment (CBL) through an interconnect element 352 that includes a contact located in the upper portion of the transistor layer 200, a first via located in the bottom via layer 201, a landing pad located in the first metal layer 202, and a second via located in the first via layer 203. The second source/drain region of the second pass-gate transistor (PG2) of the first memory cell (100a) and the second source/drain region of the second pass-gate transistor (PG2) of the second memory cell (100b) are electrically connected to the inverting bit line segment (CBLB) through an interconnect element 353 that includes a contact located in the upper portion of the transistor layer 200, a first via located in the bottom via layer 201, a landing pad located in the first metal layer 202, and a second via located in the first via layer 203. The second VSS line segment (CVSSL2) is electrically connected to the first VSS line segment (CVSSL1) through a via 361 that is located in the first via layer 203, is electrically connected to the third VSS line segment (CVSSL3) through a via 362 that is located in the second via layer 205, and is electrically connected to the fourth VSS line segment (CVSSL4) through a via 363 that is located in the second via layer 205.

With respect to each of the memory units 10, the first landing pad of the interconnect element 324, the first VDD line segment (CVDDL1), the landing pad of the interconnect element 322, the landing pad of the interconnect element 321, the first VSS line segment (CVSSL1), the landing pad of the interconnect element 342, the landing pad of the interconnect element 341, the second VDD line segment (CVDDL2) and the first landing pad of the interconnect element 344 are aligned in the X direction in the given order.

In some embodiments, each of the transistors (PU1, PU2, PD1, PD2, PG1, PG2) of the memory cells (100a, 100b) of the memory units 10 may be a planar field effect transistor (planar FET), a three-dimensional field effect transistor (3D FET) such as a fin field effect transistor (FinFET), a nanosheet gate-all-around field effect transistor (GAAFET), a nanowire GAAFET, a forksheet field effect transistor, a complementary field effect transistor (CFET), or other suitable FETs. FIGS. 5 and 6 depict an example where each of the transistors (PU1, PU2) of the memory cells (100a, 100b) of the memory units 10 has a p-type conductivity, and each of the transistors (PD1, PD2, PG1, PG2) of the memory cells (100a, 100b) of the memory units 10 has an n-type conductivity.

Referring to FIGS. 1 and 3 to 6, the memory cells (100a, 100b) of each of the memory units 10 are offset from each other by 180 degrees in orientation. With respect to each of the rows 101: any two adjacent ones of the memory units 10 in the row 101 are mirror symmetric with each other about a plane transverse to the X direction; the first word line segments (CWL1) of any two adjacent ones of the memory units 10 in the row 101 are in contact with each other, so the first word line segments (CWL1) of the memory units 10 in the row 101 cooperatively form the first word line (WL1) that corresponds to the row 101; the second word line segments (CWL2) of any two adjacent ones of the memory units 10 in the row 101 are in contact with each other, so the second word line segments (CWL2) of the memory units 10 in the row 101 cooperatively form the second word line (WL2) that corresponds to the row 101; the third VSS line segments (CVSSL3) of any two adjacent ones of the memory units 10 in the row 101 are in contact with each other, so the third VSS line segments (CVSSL3) of the memory units 10 in the row 101 cooperatively form a third VSS line that corresponds to the row 101; and the fourth VSS line segments (CVSSL4) of any two adjacent ones of the memory units 10 in the row 101 are in contact with each other, so the fourth VSS line segments (CVSSL4) of the memory units 10 in the row 101 cooperatively form a fourth VSS line that corresponds to the row 101.

With respect to each of the columns 102: any two adjacent ones of the memory units 10 in the column 102 are mirror symmetric with each other about a plane transverse to the Y direction; the non-inverting bit line segments (CBL) of any two adjacent ones of the memory units 10 in the column 102 are in contact with each other, so the non-inverting bit line segments (CBL) of the memory units 10 in the column 102 cooperatively form the non-inverting bit line (BL) that corresponds to the column 102; the inverting bit line segments (CBLB) of any two adjacent ones of the memory units 10 in the column 102 are in contact with each other, so the inverting bit line segments (CBLB) of the memory units 10 in the column 102 cooperatively form the inverting bit line (BLB) that corresponds to the column 102; the first VDD line segments (CVDDL1) of any two adjacent ones of the memory units 10 in the column 102 are in contact with each other, so the first VDD line segments (CVDDL1) of the memory units 10 in the column 102 cooperatively form a first VDD line that corresponds to the column 102 and that is for transmitting a first supply voltage; the second VDD line segments (CVDDL2) of any two adjacent ones of the memory units 10 in the column 102 are in contact with each other, so the second VDD line segments (CVDDL2) of the memory units 10 in the column 102 cooperatively form a second VDD line that corresponds to the column 102 and that is for transmitting the first supply voltage; the first VSS line segments (CVSSL1) of any two adjacent ones of the memory units 10 in the column 102 are in contact with each other, so the first VSS line segments (CVSSL1) of the memory units 10 in the column 102 cooperatively form a first VSS line that corresponds to the column 102 and that is for transmitting a second supply voltage lower than the first supply voltage in magnitude; and the second VSS line segments (CVSSL2) of any two adjacent ones of the memory units 10 in the column 102 are in contact with each other, so the second VSS line segments (CVSSL2) of the memory units 10 in the column 102 cooperatively form a second VSS line that corresponds to the column 102 and that is for transmitting the second supply voltage.

In some embodiments, for any two of the memory units 10 that are adjacent to each other in the Y direction (also respectively referred to as a first memory unit 10 and a second memory unit 10), one of the VSS line segments (CVSSL3, CVSSL4) of the first memory unit 10 that is close to the second memory unit 10 (e.g., the third VSS line segment (CVSSL3) of the first memory unit 10) and one of the VSS line segments (CVSSL3, CVSSL4) of the second memory unit 10 that is close to the first memory unit 10 (e.g., the third VSS line segment (CVSSL3) of the second memory unit 10) may share the same region (i.e., the first memory unit 10 and the second memory unit 10 may have a common third VSS line segment (CVSSL3) or a common fourth VSS line segment (CVSSL4)).

By virtue of the second VSS lines (cooperatively formed by the second VSS line segments (CVSSL2) of the memory units 10) electrically connecting to the first VSS lines (cooperatively formed by the first VSS line segments (CVSSL1) of the memory units 10) in parallel, and by virtue of the third VSS lines (cooperatively formed by the third VSS line segments (CVSSL3) of the memory units 10) and the fourth VSS lines (cooperatively formed by the fourth VSS line segments (CVSSL4) of the memory units 10) electrically connecting the second VSS lines together, a line resistance (in the Y direction) from a combination of the first VSS lines, the second VSS lines, the third VSS lines and the fourth VSS lines can be low, and will thus contribute to a low voltage drop. This is beneficial to reducing power consumption of the memory device, and increasing a maximum operating speed of the memory device.

In a cell region of each of the memory units 10, the second metal layer 204 is free of any VDD line segment, and the memory cells (100a, 100b) share a common non-inverting bit line segment (CBL) and a common inverting bit line segment (CBLB). This can facilitate shrinking of the memory device, and can enhance manufacturing capability of the memory device. In addition, the second metal layer 204 can have more space for disposition of the non-inverting bit line segment (CBL) and the inverting bit line segment (CBLB), each of the non-inverting bit line segment (CBL) and the inverting bit line segment (CBLB) can be made wider so as to have a low line resistance (in the Y direction), and a distance between the non-inverting bit line segment (CBL) and the second VSS line segment (CVSSL2) and a distance between the inverting bit line segment (CBLB) and the second VSS line segment (CVSSL2) can be made larger so as to reduce a parasitic capacitance of the non-inverting bit line segment (CBL) and a parasitic capacitance of the inverting bit line segment (CBLB). Therefore, the non-inverting bit lines (BL) that respectively correspond to the columns 102 and the inverting bit lines (BLB) that respectively correspond to the columns 102 can each have a low line resistance (in the Y direction) and a small parasitic capacitance, and will thus contribute to only a low resistance-capacitance (RC) time delay. This is beneficial to increasing the maximum operating speed of the memory device and reducing a minimum write voltage of the memory device.

In the cell region of each of the memory units 10, four active regions (including the first active region 51 and the second active region 52 for the first memory cell (100a), and the first active region 51 and the second active region 52 for the second memory cell (100b)) are required. This can facilitate the shrinking of the memory device, and can enhance the ability to manufacture the memory device.

By virtue of the memory device having a highly symmetric layout, component mismatch can be reduced, thereby enhancing ease of manufacturing the memory device.

In some embodiments, each of the memory cells (100a, 100b) of the memory units 10 may have a rectangular cell region, and a ratio of a dimension of the rectangular cell region of the memory cell (100a/100b) in the Y direction to a dimension of the rectangular cell region of the memory cell (100a/100b) in the X direction may fall within a range of from about 1.2 to about 2.5.

In some embodiments, with respect to each of the memory cells (100a, 100b) of the memory units 10, a dimension of the memory cell (100a/100b) in the Y direction may be substantially equal to 4×PG, where PG denotes a minimum pitch of the gate electrodes of the transistors (PU1, PU2, PD1, PD2, PG1, PG2). A pitch of components is defined as a dimension between two adjacent components (measured from the same locations, such as center to center, or left edge to left edge). The pitch may not be a constant, so the minimum pitch is defined and constrained in designing the memory device.

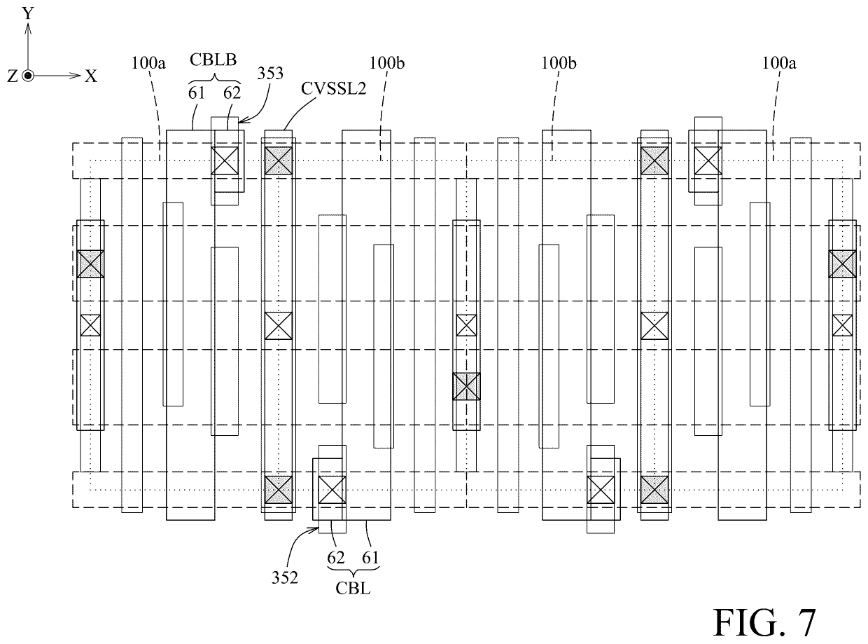

FIG. 7 is a schematic diagram illustrating relative positions (in the X direction and the Y direction) of various components of a memory device in accordance with some embodiments. It should be noted that FIG. 7 omits the depiction of some components of the memory device for the sake of clarity. Referring to FIGS. 1, 5 and 7, the memory device depicted in FIGS. 1, 5 and 7 is similar to the memory device described with reference to FIGS. 1 to 6, but differs therefrom in that, with respect to each of the memory cells (100a, 100b) of the memory units 10, each of the non-inverting bit line segment (CBL) and the inverting bit line segment (CBLB) has a first rectangular portion 61 that extends along the Y direction, and a second rectangular portion 62 that extends from the first rectangular portion 61 toward the second VSS line segment (CVSSL2) along the X direction. The second rectangular portion 62 of the non-inverting bit line segment (CBL) is electrically connected to the second source/drain region of the first pass-gate transistor (PG1) of the first memory cell (100a) and the second source/drain region of the first pass-gate transistor (PG1) of the second memory cell (100b) through the interconnect element 352. The second rectangular portion 62 of the inverting bit line segment (CBLB) is electrically connected to the second source/drain region of the second pass-gate transistor (PG2) of the first memory cell (100a) and the second source/drain region of the second pass-gate transistor (PG2) of the second memory cell (100b) through the interconnect element 353. Therefore, an average distance between the non-inverting bit line segment (CBL) and the second VSS line segment (CVSSL2) and an average distance between the inverting bit line segment (CBLB) and the second VSS line segment (CVSSL2) can be increased, thereby reducing the parasitic capacitance of the non-inverting bit line segment (CBL) and the parasitic capacitance of the inverting bit line segment (CBLB). This can reduce the power consumption of the memory device, and can increase the maximum operating speed of the memory device.

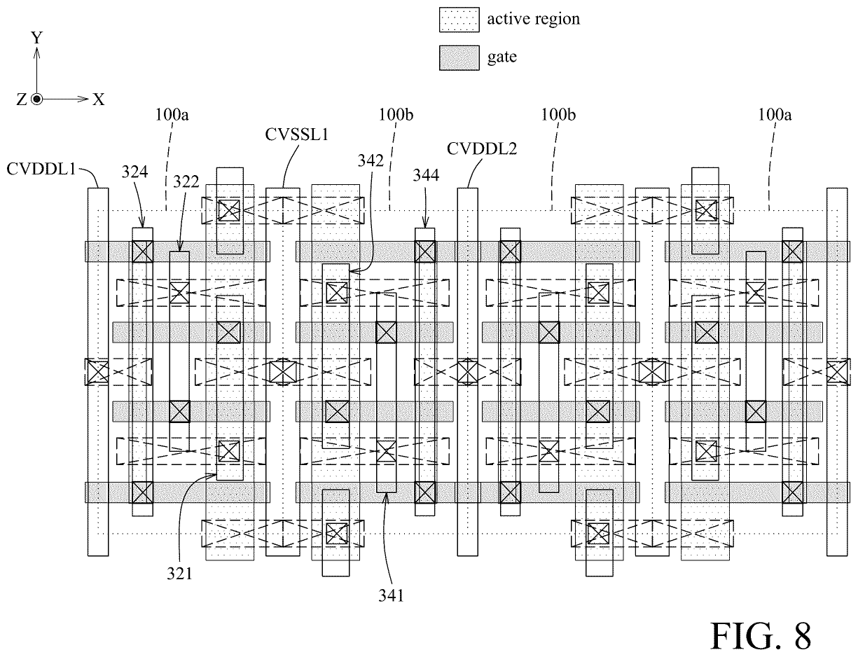

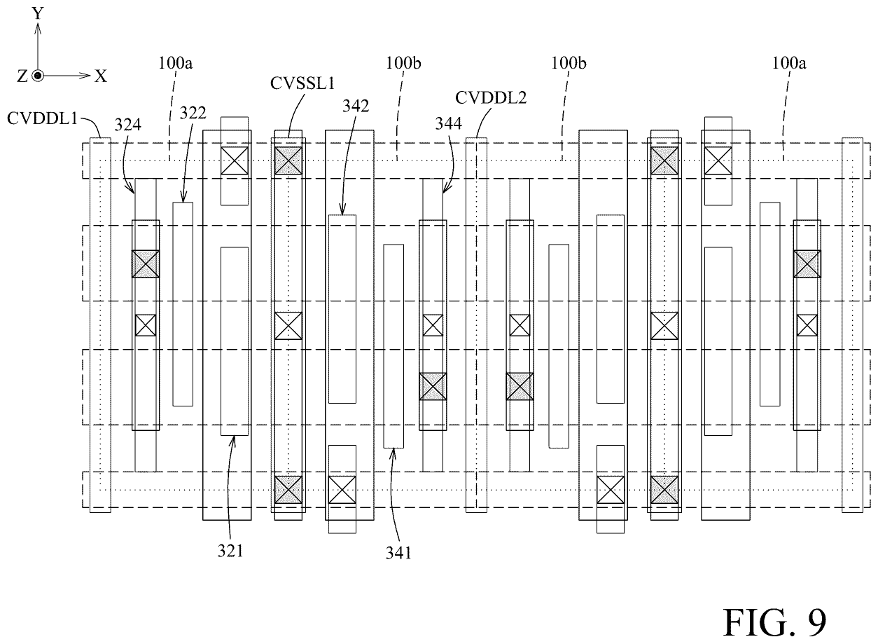

FIGS. 8 and 9 are schematic diagrams illustrating relative positions (in the X direction and the Y direction) of various components of a memory device in accordance with some embodiments. It should be noted that each of FIGS. 8 and 9 omits the depiction of some components of the memory device for the sake of clarity. Referring to FIGS. 1, 8 and 9, the memory device depicted in FIGS. 1, 8 and 9 is similar to the memory device described with reference to FIGS. 1 to 6, but differs therefrom in that, with respect to each of the memory units 10, the first VDD line segment (CVDDL1), the first landing pad of the interconnect element 324, the landing pad of the interconnect element 322, the landing pad of the interconnect element 321, the first VSS line segment (CVSSL1), the landing pad of the interconnect element 342, the landing pad of the interconnect element 341, the first landing pad of the interconnect element 344 and the second VDD line segment (CVDDL2) are aligned in the X direction in the given order.

In some embodiments, for any two of the memory units 10 that are adjacent to each other in the X direction (also respectively referred to as a first memory unit 10 and a second memory unit 10), one of the VDD line segments (CVDDL1, CVDDL2) of the first memory unit 10 that is close to the second memory unit 10 (e.g., the second VDD line segment (CVDDL2) of the first memory unit 10 as depicted in FIGS. 8 and 9) and one of the VDD line segments (CVDDL1, CVDDL2) of the second memory unit 10 that is close to the first memory unit 10 (e.g., the second VDD line segment (CVDDL2) of the second memory unit 10 as depicted in FIGS. 8 and 9) may share the same region (i.e., the first memory unit 10 and the second memory unit 10 may have a common first VDD line segment (CVDDL1) or a common second VDD line segment (CVDDL2)).

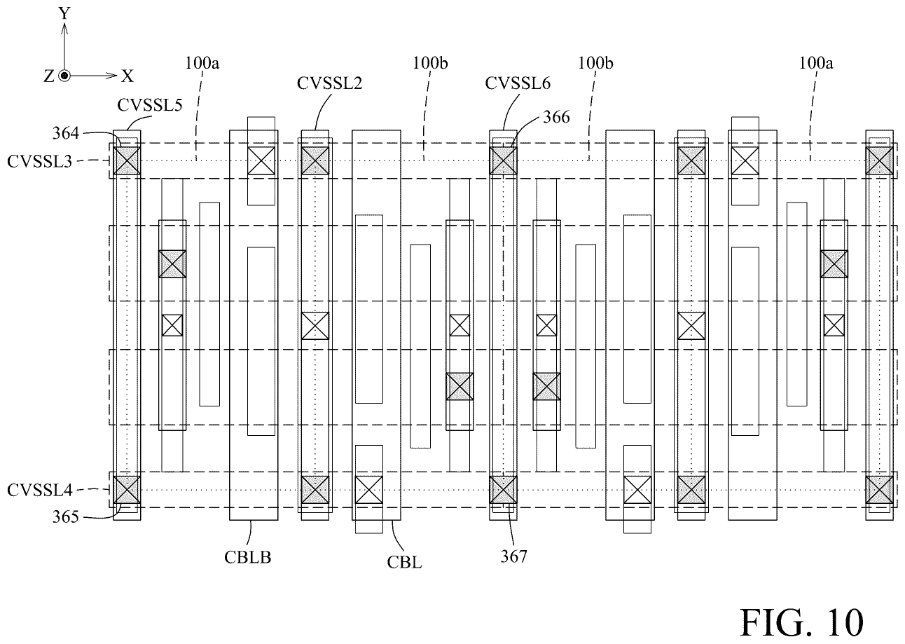

FIG. 10 is a schematic diagram illustrating relative positions (in the X direction and the Y direction) of various components of a memory device in accordance with some embodiments. It should be noted that FIG. 10 omits the depiction of some components of the memory device for the sake of clarity. Referring to FIGS. 1, 5 and 10, the memory device depicted in FIGS. 1, 5 and 10 is similar to the memory device described with reference to FIGS. 1 to 6, but differs therefrom in that each of the memory units 10 further includes a fifth VSS line segment (CVSSL5) and a sixth VSS line segment (CVSSL6). With respect to each of the memory units 10, the fifth VSS line segment (CVSSL5) and the sixth VSS line segment (CVSSL6) are located in the second metal layer 204 (see FIG. 4), and each extend along the Y direction. The inverting bit line segment (CBLB) is disposed between the second VSS line segment (CVSSL2) and the fifth VSS line segment (CVSSL5). The non-inverting bit line segment (CBL) is disposed between the second VSS line segment (CVSSL2) and the sixth VSS line segment (CVSSL6). With respect to each of the columns 102: the fifth VSS line segments (CVSSL5) of any two adjacent ones of the memory units 10 in the column 102 are in contact with each other, so the fifth VSS line segments (CVSSL5) of the memory units 10 in the column 102 cooperatively form a fifth VSS line that corresponds to the column 102 and that is for transmitting the second supply voltage; and the sixth VSS line segments (CVSSL6) of any two adjacent ones of the memory units 10 in the column 102 are in contact with each other, so the sixth VSS line segments (CVSSL6) of the memory units 10 in the column 102 cooperatively form a sixth VSS line that corresponds to the column 102 and that is for transmitting the second supply voltage.

In some embodiments, for any two of the memory units 10 that are adjacent to each other in the X direction (also respectively referred to as a first memory unit 10 and a second memory unit 10), one of the VSS line segments (CVSSL5, CVSSL6) of the first memory unit 10 that is close to the second memory unit 10 (e.g., the sixth VSS line segment (CVSSL6) of the first memory unit 10 as depicted in FIG. 10) and one of the VSS line segments (CVSSL5, CVSSL6) of the second memory unit 10 that is close to the first memory unit 10 (e.g., the sixth VSS line segment (CVSSL6) of the second memory unit 10 as depicted in FIG. 10) may share the same region (i.e., the first memory unit 10 and the second memory unit 10 may have a common fifth VSS line segment (CVSSL5) or a common sixth VSS line segment (CVSSL6)).

By virtue of the fifth VSS lines (cooperatively formed by the fifth VSS line segments (CVSSL5) of the memory units 10) and the sixth VSS lines (cooperatively formed by the sixth VSS line segments (CVSSL6) of the memory units 10) electrically connecting to the second VSS lines in parallel, a line resistance (in the Y direction) from a combination of the first VSS lines, the second VSS lines, the third VSS lines, the fourth VSS lines, the fifth VSS lines and the sixth VSS lines can be low, and will thus contribute to a low voltage drop. This is beneficial for reducing the power consumption of the memory device, and increasing the maximum operating speed of the memory device.

In accordance with some embodiments of the present disclosure, a memory unit includes a first memory cell, a second memory cell, a first VDD line segment, a non-inverting bit line segment and an inverting bit line segment. The first memory cell and the second memory cell are located in a transistor layer, and are adjacent to each other in a first direction. The first VDD line segment is located in a first metal layer stacked on the transistor layer, extends along a second direction, and is electrically connected to the first memory cell. The non-inverting bit line segment and the inverting bit line segment are located in a second metal layer stacked on the first metal layer, each extend along the second direction, and each are electrically connected to the first memory cell and the second memory cell.

In accordance with some embodiments of the present disclosure, the memory unit further includes a first word line segment and a second word line segment. The first word line segment and the second word line segment are located in a third metal layer stacked on the second metal layer, and each extend along the first direction, where the first word line segment is electrically connected to the first memory cell, and the second word line segment is electrically connected to the second memory cell.

In accordance with some embodiments of the present disclosure, the memory unit further includes two VSS line segments. The VSS line segments are located in the third metal layer, and each extend along the first direction. The first word line segment and the second word line segment are disposed between the VSS line segments.

In accordance with some embodiments of the present disclosure, the memory unit further includes a first VSS line segment. The first VSS line segment is located in the first metal layer, extends along the second direction, and is electrically connected to the first memory cell and the second memory cell.

In accordance with some embodiments of the present disclosure, the memory unit further includes a second VSS line segment and a third VSS line segment. The second VSS line segment is located in the second metal layer, extends along the second direction, and is electrically connected to the first VSS line segment. The third VSS line segment is located in a third metal layer stacked on the second metal layer, extends along the first direction, and is electrically connected to the second VSS line segment.

In accordance with some embodiments of the present disclosure, the second VSS line segment is disposed between the non-inverting bit line segment and the inverting bit line segment.

In accordance with some embodiments of the present disclosure, the memory unit further includes a first additional VSS line segment and a second additional VSS line segment. The first additional VSS line segment and the second additional VSS line segment are located in the second metal layer, each extend along the second direction, and each are electrically connected to the third VSS line segment. The inverting bit line segment is disposed between the second VSS line segment and the first additional VSS line segment, and the non-inverting bit line segment is disposed between the second VSS line segment and the second additional VSS line segment.

In accordance with some embodiments of the present disclosure, the memory unit further includes a second VDD line segment. The second VDD line segment is located in the first metal layer, extends along the second direction, and is electrically connected to the second memory cell. The first VSS line segment is disposed between the first VDD line segment and the second VDD line segment.

In accordance with some embodiments of the present disclosure, the first memory cell has a rectangular cell region. A ratio of a dimension of the rectangular cell region of the first memory cell in the second direction to a dimension of the rectangular cell region of the first memory cell in the first direction falls within a range of from 1.2 to 2.5.

In accordance with some embodiments of the present disclosure, the first memory cell includes a plurality of transistors. Each of the plurality of transistors of the first memory cell includes a gate electrode extending along the first direction. The gate electrodes of the plurality of transistors of the first memory cell have a minimum pitch of PG. A dimension of the first memory cell in the second direction is substantially equal to 4×PG.

In accordance with some embodiments of the present disclosure, each of the non-inverting bit line segment and the inverting bit line segment has a first rectangular portion that extends along the second direction, and a second rectangular portion that extends from the first rectangular portion along the first direction and that is electrically connected to the first memory cell and the second memory cell.

In accordance with some embodiments of the present disclosure, a memory unit includes a first memory cell, a second memory cell, a non-inverting bit line segment, an inverting bit line segment, a first word line segment and a second word line segment. The first memory cell and the second memory cell are adjacent to each other in a first direction. Each of the non-inverting bit line segment and the inverting bit line segment extends along a second direction, and is electrically connected to the first memory cell and the second memory cell. Each of the first word line segment and the second word line segment extends along the first direction, where the first word line segment is electrically connected to the first memory cell, and the second word line segment is electrically connected to the second memory cell.

In accordance with some embodiments of the present disclosure, the non-inverting bit line segment and the inverting bit line segment are located in a metal layer that is free of any VDD line segment.

In accordance with some embodiments of the present disclosure, the first memory cell includes a plurality of transistors. Some of the plurality of transistors of the first memory cell are formed in a first active region, and the other ones of the plurality of transistors of the first memory cell are formed in a second active region. The first active region and the second active region are aligned in the first direction, and each extend along the second direction.

In accordance with some embodiments of the present disclosure, the first memory cell includes a plurality of transistors. Each of the plurality of transistors of the first memory cell includes a gate electrode extending along the first direction. The gate electrodes of the plurality of transistors of the first memory cell have a minimum pitch of PG. A dimension of the first memory cell in the second direction is substantially equal to 4×PG.

In accordance with some embodiments of the present disclosure, the first memory cell has a rectangular cell region. A ratio of a dimension of the rectangular cell region of the first memory cell in the second direction to a dimension of the rectangular cell region of the first memory cell in the first direction falls within a range of from 1.2 to 2.5.

In accordance with some embodiments of the present disclosure, a memory unit includes a first memory cell, a second memory cell, a first VSS line segment, a non-inverting bit line segment, an inverting bit line segment, a second VSS line segment and a third VSS line segment. The first memory cell and the second memory cell are located in a transistor layer, and are adjacent to each other in a first direction. The first VSS line segment is located in a first metal layer stacked on the transistor layer, extends along a second direction, and is electrically connected to the first memory cell and the second memory cell. The non-inverting bit line segment, the inverting bit line segment and the second VSS line segment are located in a second metal layer stacked on the first metal layer, and each extend along the second direction, where each of the non-inverting bit line segment and the inverting bit line segment is electrically connected to the first memory cell and the second memory cell, and the second VSS line segment is electrically connected to the first VSS line segment. The third VSS line segment is located in a third metal layer stacked on the second metal layer, extends along the first direction, and is electrically connected to the second VSS line segment.

In accordance with some embodiments of the present disclosure, the second VSS line segment is disposed between the non-inverting bit line segment and the inverting bit line segment.

In accordance with some embodiments of the present disclosure, the memory unit further includes a first VDD line segment and a second VDD line segment. The first VDD line segment and the second VDD line segment are located in the first metal layer, and each extend along the second direction. The first VDD line segment is electrically connected the first memory cell, the second VDD line segment is electrically connected the second memory cell, and the first VSS line segment is disposed between the first VDD line segment and the second VDD line segment.

In accordance with some embodiments of the present disclosure, the memory unit further includes a first word line segment and a second word line segment. The first word line segment and the second word line segment are located in the third metal layer, and each extend along the first direction, where the first word line segment is electrically connected to the first memory cell, and the second word line segment is electrically connected to the second memory cell.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory unit comprising:
a first memory cell and a second memory cell which are located in a transistor layer, and which are adjacent to each other in a first direction;
a first VDD line segment which is located in a first metal layer stacked on the transistor layer, which extends along a second direction, and which is electrically connected to the first memory cell; and
a non-inverting bit line segment and an inverting bit line segment which are located in a second metal layer stacked on the first metal layer, each of which extends along the second direction, and each of which is electrically connected to the first memory cell and the second memory cell.

2. The memory unit according to claim 1, further comprising:
a first word line segment and a second word line segment which are located in a third metal layer stacked on the second metal layer, and each of which extends along the first direction, where the first word line segment is electrically connected to the first memory cell, and the second word line segment is electrically connected to the second memory cell.

3. The memory unit according to claim 2, further comprising:
two VSS line segments which are located in the third metal layer, and each of which extends along the first direction;
wherein the first word line segment and the second word line segment are disposed between the VSS line segments.

4. The memory unit according to claim 1, further comprising:
a first VSS line segment located in the first metal layer, extending along the second direction, and electrically connected to the first memory cell and the second memory cell.

5. The memory unit according to claim 4, further comprising:
a second VSS line segment located in the second metal layer, extending along the second direction, and electrically connected to the first VSS line segment; and
a third VSS line segment located in a third metal layer stacked on the second metal layer, extending along the first direction, and electrically connected to the second VSS line segment.

6. The memory unit according to claim 5, wherein:
the second VSS line segment is disposed between the non-inverting bit line segment and the inverting bit line segment.

7. The memory unit according to claim 6, further comprising:
a first additional VSS line segment and a second additional VSS line segment which are located in the second metal layer, each of which extends along the second direction, and each of which is electrically connected to the third VSS line segment;
wherein the inverting bit line segment is disposed between the second VSS line segment and the first additional VSS line segment, and the non-inverting bit line segment is disposed between the second VSS line segment and the second additional VSS line segment.

8. The memory unit according to claim 4, further comprising:
a second VDD line segment which is located in the first metal layer, which extends along the second direction, and which is electrically connected to the second memory cell;
wherein the first VSS line segment is disposed between the first VDD line segment and the second VDD line segment.

9. The memory unit according to claim 1, wherein:
the first memory cell has a rectangular cell region; and
a ratio of a dimension of the rectangular cell region of the first memory cell in the second direction to a dimension of the rectangular cell region of the first memory cell in the first direction falls within a range of from 1.2 to 2.5.

10. The memory unit according to claim 1, wherein:
the first memory cell includes a plurality of transistors;
each of the plurality of transistors of the first memory cell includes a gate electrode extending along the first direction;
the gate electrodes of the plurality of transistors of the first memory cell have a minimum pitch of PG; and
a dimension of the first memory cell in the second direction is substantially equal to 4×PG.

11. The memory unit according to claim 1, wherein:
each of the non-inverting bit line segment and the inverting bit line segment has a first rectangular portion that extends along the second direction, and a second rectangular portion that extends from the first rectangular portion along the first direction and that is electrically connected to the first memory cell and the second memory cell.

12. A memory unit comprising:
a first memory cell and a second memory cell which are adjacent to each other in a first direction;
a non-inverting bit line segment and an inverting bit line segment, each of which extends along a second direction and is electrically connected to the first memory cell and the second memory cell; and
a first word line segment and a second word line segment, each of which extends along the first direction, where the first word line segment is electrically connected to the first memory cell, and the second word line segment is electrically connected to the second memory cell.

13. The memory unit according to claim 12, wherein:
the non-inverting bit line segment and the inverting bit line segment are located in a metal layer that is free of any VDD line segment.

14. The memory unit according to claim 12, wherein:
the first memory cell includes a plurality of transistors;
some of the plurality of transistors of the first memory cell are formed in a first active region, and the other ones of the plurality of transistors of the first memory cell are formed in a second active region; and
the first active region and the second active region are aligned in the first direction, and each extend along the second direction.

15. The memory unit according to claim 12, wherein:
the first memory cell includes a plurality of transistors;
each of the plurality of transistors of the first memory cell includes a gate electrode extending along the first direction;
the gate electrodes of the plurality of transistors of the first memory cell have a minimum pitch of PG; and
a dimension of the first memory cell in the second direction is substantially equal to 4×PG.

16. The memory unit according to claim 12, wherein:
the first memory cell has a rectangular cell region; and
a ratio of a dimension of the rectangular cell region of the first memory cell in the second direction to a dimension of the rectangular cell region of the first memory cell in the first direction falls within a range of from 1.2 to 2.5.

17. A memory unit comprising:
a first memory cell and a second memory cell which are located in a transistor layer, and which are adjacent to each other in a first direction;
a first VSS line segment which is located in a first metal layer stacked on the transistor layer, which extends along a second direction, and which is electrically connected to the first memory cell and the second memory cell;
a non-inverting bit line segment, an inverting bit line segment and a second VSS line segment which are located in a second metal layer stacked on the first metal layer, and each of which extends along the second direction, where each of the non-inverting bit line segment and the inverting bit line segment is electrically connected to the first memory cell and the second memory cell, and the second VSS line segment is electrically connected to the first VSS line segment; and
a third VSS line segment which is located in a third metal layer stacked on the second metal layer, which extends along the first direction, and which is electrically connected to the second VSS line segment.

18. The memory unit according to claim 17, wherein:
the second VSS line segment is disposed between the non-inverting bit line segment and the inverting bit line segment.

19. The memory unit according to claim 17, further comprising:
a first VDD line segment and a second VDD line segment which are located in the first metal layer, and each of which extends along the second direction;
wherein the first VDD line segment is electrically connected the first memory cell, the second VDD line segment is electrically connected the second memory cell, and the first VSS line segment is disposed between the first VDD line segment and the second VDD line segment.

20. The memory unit according to claim 17, further comprising:
a first word line segment and a second word line segment which are located in the third metal layer, and each of which extends along the first direction, where the first word line segment is electrically connected to the first memory cell, and the second word line segment is electrically connected to the second memory cell.
